(19) United States
(12) Patent Application Publication
(10) Pub. No.: US 2023/0197675 A1
(43) Pub. Date: Jun. 22, 2023

(54) PACKAGING ARCHITECTURE WITH INTEGRATED CIRCUIT DIES OVER INPUT/OUTPUT INTERFACES

(71) Applicant: Intel Corporation, Santa Clara, CA (US)

(72) Inventors: Gerald S. Pasdast, San Jose, CA (US); Yidnekachew Mekonnen, Chandler, AZ (US); Adel A. Elsherbini, Tempe, AZ (US); Peipei Wang, San Jose (US); Vivek Kumar Rajan, Portland, OR (US); Georgios Dogiamis, Chandler, AZ (US)

(73) Assignee: Intel Corporation, Santa Clara, CA (US)

(21) Appl. No.: 17/552,845

(22) Filed: Dec. 16, 2021

(51) Int. Cl. H01L 25/065; H01L 23/48; H01L 23/00

(52) U.S. Cl. CPC H01L 25/0652; H01L 23/481; H01L 24/16; H01L 2224/16225; H01L 2924/37001

(57) ABSTRACT

Embodiments of the present disclosure provide a microelectronic assembly comprising: a first integrated circuit (IC) die, the first IC die comprising an input/output (IO) circuit; and a plurality of IC dies, the plurality of IC dies comprising a second IC die, the second IC die comprising a microcontroller circuit to control the IO circuit, wherein the first IC die and the plurality of IC dies are coupled with interconnects having a pitch of less than 10 micrometers between adjacent ones of the interconnects.

### TECHNICAL FIELD

The present disclosure relates to techniques, methods, and apparatus directed to packaging architecture with integrated circuit (IC) dies over input/output (IO) interfaces.

### BACKGROUND

Electronic circuits when commonly fabricated on a wafer of semiconductor material, such as silicon, are called ICs. The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a simplified top view of an example microelectronic assembly according to some embodiments of the present disclosure.

FIG. 2 is a simplified cross-sectional view of the example microelectronic assembly of FIG. 1, according to an embodiment of the present disclosure.

FIG. 3 is a simplified cross-sectional view of the example microelectronic assembly of FIG. 1, according to another embodiment of the present disclosure.

FIG. 4 is a simplified cross-sectional view of the example microelectronic assembly of FIG. 1, according to yet another embodiment of the present disclosure.

FIG. 5 is a simplified top view and block diagram of an example IO circuit, according to some embodiments of the present disclosure.

FIG. 6 is a simplified cross-sectional view of the example microelectronic assembly of FIG. 1, according to yet another embodiment of the present disclosure.

FIG. 7 is a simplified cross-sectional view of another example microelectronic assembly, according to embodiments of the present disclosure.

FIG. 8 is a simplified cross-sectional view of a hybrid bond in the example microelectronic assembly of FIG. 1, according to various embodiments.

FIG. 9 is a cross-sectional view of a device package that includes one or more microelectronic assemblies in accordance with any of the embodiments disclosed herein.

FIG. 10 is a cross-sectional side view of a device assembly that includes one or more microelectronic assemblies in accordance with any of the embodiments disclosed herein.

FIG. 11 is a block diagram of an example computing device that includes one or more microelectronic assemblies in accordance with any of the embodiments disclosed herein.

### DETAILED DESCRIPTION

### Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

Advances in semiconductor processing and logic design have permitted an increase in the amount of logic circuits that may be included in processors and other IC devices. As a result, many processors now have multiple cores that are monolithically integrated on a single die. Generally, these types of monolithic ICs are also described as planar since they take the form of a flat surface and are typically built on a single silicon wafer made from a monocrystalline silicon boule. The typical manufacturing process for such monolithic ICs is called a planar process, allowing photolithography, etching, heat diffusion, oxidation, and other such processes to occur on the surface of the wafer, such that active circuit elements (e.g., transistors and diodes) are formed on the planar surface of the silicon wafer.

Current technologies permit hundreds and thousands of such active circuit elements to be formed on a single die so that numerous logic circuits may be enabled thereon. In such monolithic dies, the manufacturing process must be optimized for all the circuits equally, resulting in trade-offs between different circuits. In addition, because of the limitation of having to place circuits on a planar surface, some circuits are farther apart from some others, resulting in decreased performance such as longer delays. The manufacturing yield may also be severely impacted because the entire die may have to be discarded if even one circuit is malfunctional.

One solution to overcome such negative impacts of monolithic dies is to disaggregate the circuits into smaller IC dies (e.g., chiplets, tiles) electrically coupled by interconnect bridges. The smaller dies are part of an assembly of interconnected dies that together form a complete IC in terms of application and/or functionality, such as a memory chip, microprocessor, microcontroller, commodity IC (e.g., chip used for repetitive processing routines, simple tasks, application specific IC, etc.), and system-on-a-chip (SOC). In other words, the individual dies are connected together to create the functionalities of a monolithic IC. By using separate dies, each individual die can be designed and manufactured optimally for a particular functionality. For example, a processor core that contains logic circuits might aim for performance, and thus might require a very speed-optimized layout. This has different manufacturing requirements compared to a Universal Serial Bus (USB) controller, which is built to meet certain USB standards, rather than for processing speed. Thus, by having different parts of the overall design separated into different dies, each one optimized in terms of design and manufacturing, the overall yield and cost of the combined die solution may be improved.

The connectivity between these dies is achievable by many different ways. For example, in 2.5D packaging solutions, a silicon interposer and through-substrate vias (TSVs), also called through-silicon vias where the substrate is silicon, connect dies at silicon-interconnect speed in a minimal footprint. In another example, interconnect bridges (e.g., Embedded Multi-Die Interconnect Bridge (EMIB™), embedded under the edges of two interconnecting dies facilitates electrical coupling between them. In a three-dimensional (3D) architecture, the dies are stacked one above the other, creating a smaller footprint overall. Typically, the electrical connectivity and mechanical coupling in such 3D architecture is achieved using TSVs and high-pitch solder-based bumps (e.g., C2 interconnections). The EMIB and the 3D stacked architecture may also be combined using an omni-directional interconnect (ODI), in which EMIB chips are embedded in an organic mold compound, which allows for top-packaged chips to communicate with other chips horizontally using EMIB and vertically, using through-mold vias (TMVs) which are typically larger than TSVs. However, these current interconnect technologies use solder or its equivalent for connectivity, with consequent low vertical and horizontal interconnect density. For example, typical flip-chip solder bumps have a pitch of 112-150 micrometers, and a hundred of such bumps having a pitch of 112 micrometers will occupy an area of approximately 1.21 square millimeters.

For most IC die designs, logic and memory fill the center of a chip and IO is on the periphery, and the IO size is impacted by the number of lanes or data channels. For example, a general-purpose IO (GPIO) of Intel's Agilex interface system comprises two IO circuits, one placed near the periphery of the IC die, and another placed near a field programmable gate array (FPGA) core farther from the periphery of the IC die. In each such IO circuit, there are 4 IO lanes with 12 IO pins in each lane that make up a total of 48 single-ended IO pins or 24 differential IO pairs. In another example, IC dies for networking and data center applications may comprise around 120 to 200 lanes of serializer/deserializer (SerDes) in the IO area. As the number of IO instantiations and IO lane count grow over time for future IC die designs, in addition to complexity of mentioned IO circuit architectures to reach ever faster speeds, a greater percentage of overall SOC die area is consumed generationally by “uncore” (i.e., non-compute) portions of SOCs, which include IO circuits and analog circuits such as phase-locked-loops (PLLs), integrated power regulators, and others).

In this regard, a quasi-monolithic hierarchical integration architecture using recursively coupled plurality of dies to form microelectronic assemblies helps to mitigate several drawbacks mentioned above. The plurality of dies may comprise active dies and/or passive dies, and at least a portion in the plurality of dies are coupled using die-to-die (DTD) interconnects with sub-10 micrometer pitch, also referred to as “hybrid bonds,” “hybrid interconnects,” or “direct bond interconnects.” In other words, the center-to-center separation between adjacent high-density interconnects is less than or equal to 10 micrometers. In such quasi-monolithic structures, IC dies are stacked in multiple layers with inorganic dielectric between the layers and around the IC dies. By using hybrid bonds or equivalent, having a pitch of less than 10 micrometers, an effective interconnection area may be reduced considerably from a corresponding interconnection area having the same number of flip-chip interconnects. For example, with 9 micrometer pitch, 100 hybrid bonds will occupy an effective area of approximately 0.0081 square millimeters, which is several orders of magnitude smaller than (e.g., 151.25× shrink factor) with flip-chip interconnects having a pitch of 112 micrometers. Electrical coupling through the dielectric is implemented with through-dielectric vias (TDVs) that are pass-through structures, i.e., they provide an electrical pathway between layers without any intermediate circuitry.

Embodiments of the present disclosure provide a microelectronic assembly comprising: a first IC die, the first IC die comprising an IO circuit; and a plurality of IC dies, the plurality of IC dies comprising a second IC die, the second IC die comprising a microcontroller circuit to control the IO circuit. The first IC die and the plurality of IC dies are coupled with interconnects having a pitch of less than 10 micrometers between adjacent ones of the interconnects. Such interconnects may be distributed with interconnect density greater than 10,000 connections per square millimeter in some embodiments, proportional and of the same order of magnitude as trace pitch and/or via density that is generally found within an IC die (e.g., in metallization stacks of the IC die above the active region) as opposed to interconnect density between IC dies of older packaging technologies (e.g., solder-based C4 or larger interconnects). Interconnects arranged with such interconnect density may have pitch ranging between 0.5 micrometer and 10 micrometers (i.e., in one embodiment, the interconnects may have a pitch of 0.5 micrometer; in another embodiment, the interconnects may have a pitch of 2 micrometer; in some embodiments, some interconnects may have a pitch of 0.5 micrometer whereas other interconnects may have a pitch of 8 micrometers, etc.).

Embodiments of the present disclosure also provide an IC package comprising: a first IC die comprising an IO circuit at a periphery of the first IC die (e.g., at least one edge of the IO circuit is between 10 micrometers and 100 micrometers from the edge of the first IC die); a second IC die comprising a microcontroller circuit to control the IO circuit; and a package substrate coupled to the first IC die. The first IC die is between the second IC die and the package substrate, the second IC die is located adjacent to the IO circuit of the first IC die, the first IC die and the second IC die are coupled with first interconnects having a first pitch of less than 10 micrometers between adjacent ones of the interconnects, and the first IC die and the package substrate are coupled with second interconnects having a second pitch of greater than 10 micrometers between adjacent ones of the interconnects.

Embodiments of the present disclosure also provide an IC comprising: an IO physical (PHY) interface comprising a data register; and a microcontroller circuit conductively coupled to the data register. The IO PHY interface is in a first IC die, the microcontroller circuit is in a second IC die, and the first IC die and the second IC die are coupled by interconnects having a pitch of less than 10 micrometers.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a semiconductor-on-insulator (SOI, e.g., a silicon-on-insulator) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field effect transistors (FETs), e.g., metal-oxide semiconductor field effect transistors (MOSFETs). In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides (e.g., structures that guide and confine light waves), including optical fiber, optical splitters, optical combiners, optical couplers, and optical vias.

The term “conductive trace” may be used to describe an electrically conductive element isolated by an insulating material. Within IC dies, such insulating material comprises interlayer low-k dielectric that is provided within the IC die. Within package substrates, and printed circuit boards (PCBs) such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substate, the term “interconnect” may also refer to, respectively, DTD interconnects and die-to-package substrate (DTPS) interconnects.

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be unpackaged dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

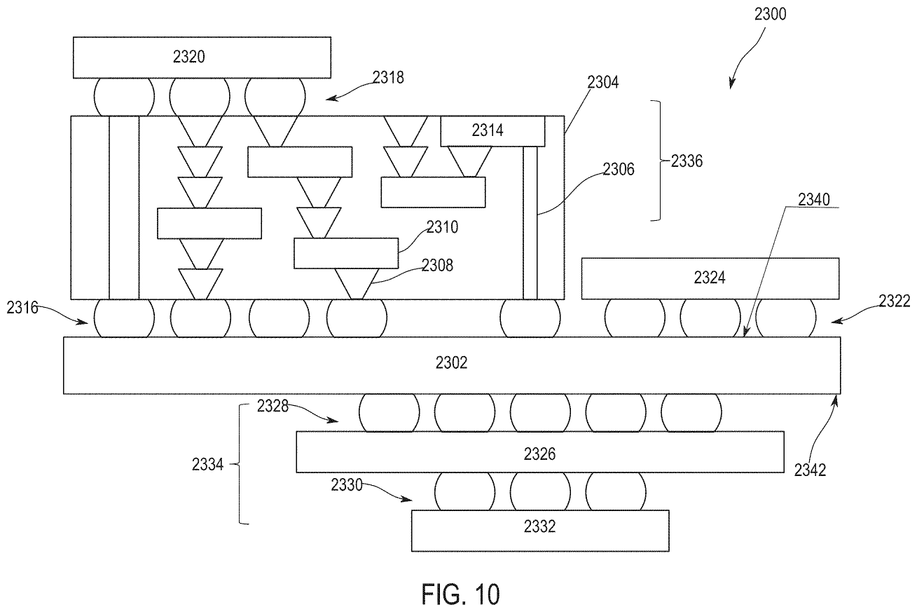

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

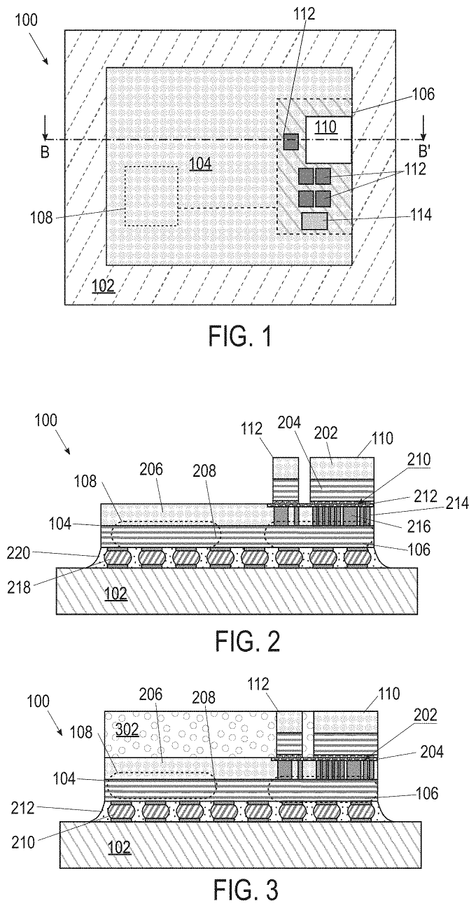

FIG. 1A is a simplified cross-sectional view of a microelectronic assembly 100 according to some embodiments of the present disclosure. Microelectronic assembly 100 comprises a package substrate 102 coupled to an IC die 104 comprising an IO circuit 106. IO circuit 106 comprises one or more circuits to implement PHY interface functions of the Open Systems Interconnection (OSI) model for electronic transmission of electrical signals into and from IC die 104. Examples of IO circuit 106 are Ethernet PHY, comprising analog circuits; Peripheral Component Interconnect Express (PCIe) PHY comprising analog circuits; wireless local area network (LAN) PHY, comprising radio frequency (RF), analog and digital circuits; USB PHY comprising digital circuits; 3G/5G/Long-Term Evolution (LTE) PHY, comprising RF, analog and digital circuits; Bluetooth PHY, comprising RF, analog and digital circuits; I²C PHY interface comprising analog and digital circuits; etc. Any suitable circuit that provides the PHY functions of the OSI model may be comprised in IO circuit 106 within the broad scope of the embodiments. Although the specific components of IO circuit 106 depend on the particular PHY functions for which it is configured, in a general sense, IO circuit 106 may require passive components (e.g., inductors, resistors, capacitors, transformers), electrostatic discharge (ESD) protection circuits (e.g., ESD diodes), PLL clocks, timers, retimers with flip-flop circuits, repeaters, and at least one microcontroller. Although only one IO circuit 106 is shown in the figure for ease of illustration, IC die 104 may comprise any number of such IO circuits 106 within the broad scope of the embodiments.

An intellectual property (IP) core 108 may be provisioned in IC die 104. IP core 108 may be conductively coupled to IO circuit 106. As used herein, the term “IP core” refers to a circuit comprising a reusable unit of logic, cell, or IC layout design with a particular functionality and defined interface and serves as a building block in an IC die design. For example, IP cores may comprise a set of memory registers, arithmetic logic unit (ALU), power converters, peripherals, programmable microprocessors, microcontrollers, digital signal processors, analog-digital mixed-signal processing blocks, configurable computing architectures, etc. IO circuit 106 may itself comprise an example of an IP core, although IO circuit 106 is differentiated from IP core 108 herein merely to illustrate the features of the embodiments described herein. Although one IP core 108 is shown in the figure, IC die 104 may comprise numerous such IP cores within the broad scope of the embodiments. One or more IP core 108 may comprise any suitable circuits, including the same circuits or different circuits. One or more IP core 108 may be coupled to IO circuit 106.

A plurality of IC dies 110, 112, 114, etc. may be coupled to and over IC die 104 with interconnects having a pitch of less than 10 micrometers between adjacent ones of the interconnects. IC die 110 may comprise a microcontroller circuit to control IO circuit 106. In various embodiments, the microcontroller circuit may comprise any logical controller circuit used to control an IO circuit. In various embodiments, the microcontroller circuit may comprise digital circuitry. The specific components and circuit configuration of the microcontroller circuit may depend upon the functionalities of IO circuit 106. All such components and circuit configurations are included within the broad scope of the embodiments herein. In some embodiments, IC dies 112 may comprise passive components, such as inductors, capacitors, and/or resistors integrated into metallization stacks within such IC dies 112. IC dies 114 may comprise one or more ESD protection circuits (e.g., one or more ESD diodes), PLL circuits, clock circuits, timers, and other such circuits that interact with IO circuit 106 and comprise active elements, such as diodes and transistors. Although a few such IC dies 112 and 114 are shown in the figure, any fewer or greater number of IC dies 112 and 114 may be included in microelectronic assembly 100 within the broad scope of the embodiments. The number, locations, arrangement, sizes, etc. of such IC dies 110, 112, 114 on IC die 104 may be determined by various operational, manufacturing, cost, and other considerations and any such number, locations, arrangement, sizes, etc. may be included within the broad scope of the embodiments of microelectronic assembly 100.

Separating out portions of a typical IO circuit of a monolithic IC into individual IC dies and stacking them one over another with interconnects having a pitch of less than 10 micrometers as in example embodiments of microelectronic assembly 100 may facilitate reducing an overall footprint of microelectronic assembly 100 without proportional functional degradation. In various embodiments, stacked IC dies 110, 112, 114, comprise functionality configured to operate with IO circuit 106 and other IP cores, including RF, analog and digital IP cores. In various embodiments, one or more of IC dies 110, 112, and 114 may include ESD protection circuits (e.g., one or more ESD diodes), resistors, inductors (e.g., T-coils, spiral inductors, tuned Q-factors for high-precision applications, etc.), microcontrollers for IO training functionality, IO logical PHY controllers, PLLs for IO or controller clocking, power supply regulators (e.g., fully integrated voltage regulator (FIVR) or similar), power supply filtering capacitors (high capacity metal-insulator-metal (MiM) or similar with medium/low frequency response, high frequency response, etc.), global or localized clock distribution networks, etc.

Such stacked configuration can be advantageous in multiple ways including by reducing the IO circuit area footprint, reducing on-die routing congestion, and improving analog performance due to optimized process node selection. Smaller bumps than in conventional flip-chip interconnects enabled by hybrid bonding facilitate implementation of stacked IC dies without significant performance degradation if the pitch of the hybrid bonds is at least an order of magnitude lower than traditional flip-chip bump pitches. Further, IC die 110 may be fabricated using semiconductor processes tailored to improve performance of the microcontroller circuit, whereas IC die 104 may be fabricated using another semiconductor process tailored to improve performance of the circuits comprised therein. As a result, in some embodiments, transistors in the microcontroller circuit of IC die 110 may be smaller than transistors in IO circuit 106 of IC die 104. Likewise, IC dies 112 and 114 may be fabricated using processes suitable for components therein, which may not be suitable for components in IC die 104. For example, IC die 112 may be fabricated using a process suitable for an inductor, whereas IC die 104 may be fabricated using a process suitable for digital circuits. As a result, the inductors (and/or other passive components) in IC die 112 may be better performing (e.g., low noise, low parasitics, etc.) than those in IC die 104.

In an example embodiment, IO circuit 106 may be located proximate to a periphery of IC die 104 (e.g., at least one edge of IO circuit 106 is located between 10 micrometers and 100 micrometers from the edge of IC die 104). By “edge” of an IC die is meant the boundary of circuitry in the IC die. In some IC dies, the physical edge of the IC die may have scribe lines (also called saw street), that may be around 100 micrometers in width, in which case IO circuit 106 may be located around 10 micrometers to 100 micrometers from such scribe line in IC die 104. IC die 110 may also be located proximate to the periphery of IC die 104 and adjacent to and over IO circuit 106. In some embodiments, IO circuit 106 may be within a boundary of a footprint (e.g., parallel projection, i.e., mapping of a three-dimensional object into a two-dimensional plane, shadow, etc.) of IC die 110. In other words, a footprint of IC die 110 may fit within a boundary of IO circuit 106 and vice versa. Conductive traces between IO circuit 106 and the plurality of IC dies 110, 112 and 114 may facilitate electrical coupling therebetween. In particular, a portion of the conductive traces may be in IC die 104, whereas another portion of the conductive traces may be in IC die 110. In some embodiments, the conductive traces, or at least a portion of the conductive traces, may be comprised in a routing layer between IC die 104 and the plurality of IC dies 110, 112 and 114.

In some embodiments, package substrate 102 may comprise multiple layers of conductive traces embedded in one or more layers of organic dielectric. For example, package substrate 102 may comprise a laminate substrate with several layers of metal planes or traces that are interconnected to each other by through-hole plated vias, with IO routing planes on the top and bottom layers, while the inner layers are used as a ground and power plane. In other embodiments, package substrate 102 may comprise an organic interposer; in yet other embodiments, package substrate 102 may comprise an inorganic interposer (e.g., made of glass, ceramic or semiconductor materials). In yet other embodiments, package substrate 102 may comprise a composite of organic and inorganic materials, for example, with an embedded semiconductor die in an organic substrate.

Note that in FIG. 1, although some components of the assembly are illustrated as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components. Note that FIG. 1 and subsequent figures are intended to show relative arrangements of the components within their assemblies, and that, in general, such assemblies may include other components that are not illustrated (e.g., various interfacial layers or various other components related to optical functionality, electrical connectivity, or thermal mitigation). For example, in some further embodiments, the assemblies as shown in FIG. 1 and subsequent figures may include more dies along with other electrical components.

FIG. 2 is a simplified cross-sectional view of an example embodiment of microelectronic assembly 100 across axis BB′ of FIG. 1, according to various embodiments of the present disclosure. IC dies 110, 112 and 114 (not shown) may be stacked over IO circuit 106 of IC die 104. In many embodiments, IC dies 110, 112 and 114 (not shown) may be arranged to fit within a boundary of IO circuit 106. In other embodiments, IC die 110 may entirely overlap with IO circuit 106 so that IC dies 112 and 114 may be disposed outside the boundary of IO circuit 106.

IC die 110 may comprise a substrate 202 and a metallization stack 204 parallel and adjacent to substrate 202. In some embodiments, portions of an active region (not shown) comprising isolated transistors, diodes, and other active elements of the microcontroller circuit may be disposed in substrate 202 and other portions of the active region may be disposed in metallization stack 204 in some embodiments. Substrate 202 may comprise materials discussed in the paragraphs above relating to substrates (e.g., base material) of IC dies. Metallization stack 204 may include interlayer dielectric (ILD) and various layers of conductive material comprising conductive traces electrically coupled by conductive vias through the ILD. Other materials or/and layers, such as seed layers, adhesion layers, intermetallic compounds, not specifically shown the figure so as not to clutter the drawings may also be provided as may be known to those skilled in the art. Electrical signals, such as power and/or IO signals, may be routed to and/or from logic circuit elements (e.g., the transistors) of the active region through one or more conductive interconnect layers situated in metallization stack 204. The layers of conductive traces may comprise one or more power grids (e.g., an arrangement of conductive lines, planes and vias, that is used to provide power), signal grids (e.g., an arrangement of conductive lines, planes and vias that is used to provide signals (e.g., data)), and/or ground grids (e.g., an arrangement of conductive lines, planes and vias that is used to provide ground connection).

In some embodiments, the conductive traces within metallization stack 204 may include lines and/or vias filled with an electrically conductive material such as aluminum or copper. The lines comprising the conductive traces may be arranged to route electrical signals in a direction of a plane that is parallel with a surface of substrate 202. For example, the lines may route electrical signals in a direction in and out of the page from the perspective of FIG. 2. Vias may be arranged to route electrical signals in a direction of a plane that is perpendicular to the surface of substrate 202. In some embodiments, the vias may electrically couple lines of different conductive routing layers together.

The ILD may comprise layers between the layers of conductive traces, the ILD layers deposited over and in between the conductive traces. The ILD layers may be formed using dielectric materials known for their applicability in IC structures, such as low-k dielectric materials. Examples of dielectric materials include, but are not limited to, silicon dioxide (SiO₂), carbon-doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant. The ILD may comprise a homogeneous material, or a heterogeneous layered composite comprising more than one layer of material, or a heterogeneous matrix comprising a mixture of materials in any suitable arrangement known in the art

IC die 112 comprising passive components may also comprise the same structure as described for IC die 110, although not explicitly labeled so as not to clutter the drawing. In many embodiments, the active region may be absent in IC die 112, and metallization stack 204 may be disposed directly over substrate 202 in such embodiments. The various passive components in IC die 112 may be comprised in metallization stack 204, for example, integrated with the conductive traces. Passive components may include, by way of examples and not as limitations, inductors, capacitors, and resistors of any form, shape, structure, and type as is known in the art.

IC die 104 may comprise a substrate 206 and a metallization stack 208 parallel and adjacent to substrate 206. In some embodiments, portions of an active region (not shown) comprising isolated transistors, diodes, and other active electronic components may be disposed in substrate 206 and other portions of the active region may be disposed in metallization stack 208 in some embodiments, similar to the substrate, metallization stack and active region discussed in relation to IC die 110. Active elements of IO circuit 106 and IP core 108 may be disposed in the active region. IP core 108 may be conductively coupled to IO circuit 106 with conductive traces in metallization stack 208. In addition, IC die 104 may comprise one or more TSVs 214 and 216 through substrate 206. TSVs 214 may be configured to carry data signals, and TSVs 216 may be configured to carry power. TSVs 216 may have a larger cross-sectional dimension (e.g., measured from one point along a periphery of the cross-section to an opposite point along the periphery; distance between two farthest points across the cross-section; etc.) than TSVs 214 in some embodiments. In other embodiments, TSVs 216 may have the same or similar cross-sectional dimensions as TSVs 214. In various embodiments, TSVs 214 and 216 may be disposed through the active region into portions of metallization stack 208. In various embodiments, a cross-sectional area of TSVs 214 and 216 is proportional to the pitch of interconnects 212. In some embodiments, TSVs 214 may have a cross-sectional dimension of 1 micron and the pitch of interconnects 212 may be 2 microns. Larger pitches correspond to larger cross-sectional dimensions of TSVs. For example, in embodiments where the pitch of DTD interconnects 212 is 10 microns, TSV 214 may have a cross-sectional dimension of 5 microns. Such small dimensions of TSVs 214 and 216 may necessitate a proportionally thin IC die. For example, IC die 104 with TSV 214 and 216 may have a thickness between 10 micrometer and 50 micrometers, whereas IC die 110 without any TSVs may have a thickness of more than 100 micrometers, although in some embodiments, IC 110 may have a thickness of less than 100 micrometers.

IC die 104 may be coupled to IC dies 110 and 112 along interface 210 with DTD interconnects 212 having a pitch of less than 10 micrometers between adjacent ones of the interconnects. In the example embodiment shown, TSVs 214 and 216 provide a conductive pathway between DTD interconnects 212 and the active region of IC die 104 through substrate 206 and metallization stack 208. For example, a conductive pathway may comprise conductive traces in metallization stack 204 of IC die 110, interconnects 212 between IC die 104 and IC die 110, TSV 214, and conductive traces in metallization stack 208 of IC die 104. In another example, another conductive pathway may conductive traces in metallization stack 204 of IC die 112, interconnects 212 between IC die 104 and IC die 112, TSV 214, and conductive traces in metallization stack 208 of IC die 104. In yet another example, another conductive pathway may comprise conductive traces in metallization stack 204 of IC die 114, interconnects 212 between IC die 104 and IC die 114, TSV 214, and conductive traces in metallization stack 208 of IC die 104. In yet another example, any of the conductive pathways described above may include conductive traces laterally coupling IC dies 110, 112 and 114 through respective metallization stack 204 of each.

Conductive traces and vias in metallization stack 208 may provide other conductive pathways from the active region of IC die 104 to DTPS interconnects 218 between IC die 104 and package substrate 102. An underfill 220 between IC die 104 and package substrate 102 may provide thermo-mechanical reliability to DTPS interconnects 218. Underfill 220 may comprise materials described in the paragraphs above relating to underfills. In many embodiments, the pitch of DTPS interconnects 218 may be larger than the pitch of DTD interconnects 212.

Note that in FIG. 2 and in subsequent figures, the DTD interconnects (e.g., 212) are shown as aligned at the respective interfaces merely for ease of illustration; in actuality, some or all of them may be misaligned. In addition, there may be other components, such as bond pads, landing pads, metallization, etc. present in the assembly that are not shown in the figures to prevent cluttering.

FIG. 3 is a simplified cross-sectional view of another example embodiment of microelectronic assembly 100 across axis BB′ of FIG. 1, according to various embodiments of the present disclosure. The embodiment shown in FIG. 3 is similar to the embodiment shown in FIG. 2, except that a dielectric 302 may be over IC die 104, and surrounding IC dies 110, 112 and 114. In various embodiments, dielectric 302 may comprise inorganic materials, for example, a compound of silicon and at least one of oxygen, carbon and nitrogen, such as silicon oxide, silicon nitride, silicon carbide, silicon oxynitride, silicon carbonitride, etc. In other embodiments, dielectric 302 may comprise an organic material, such as mold compound or polyimide.

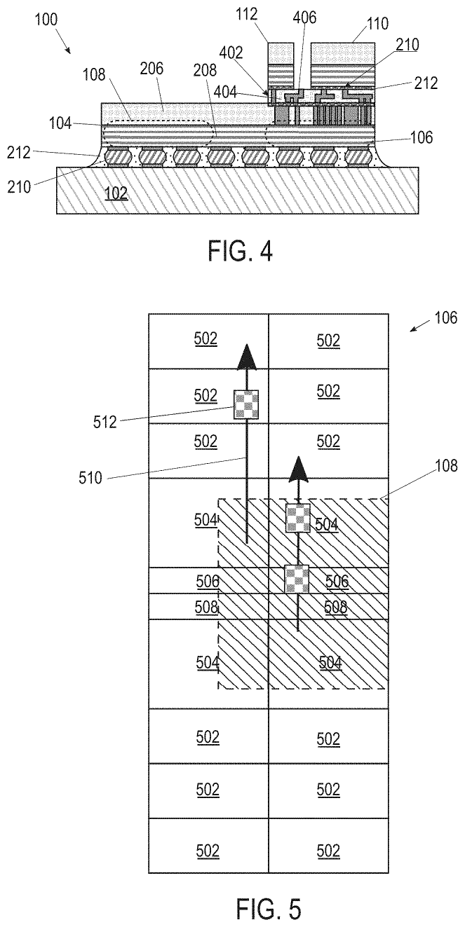

FIG. 4 is a simplified cross-sectional view of yet another example embodiment of microelectronic assembly 100 across axis BB′ of FIG. 1, according to various embodiments of the present disclosure. The embodiment shown in FIG. 3 is similar to the embodiment shown in FIG. 2, except that a routing layer 402 may be provisioned at interface 210, between IC die 104 and IC dies 110, 112 and 114. Note that although routing layer 420 is shown limited to the space contained beneath IC dies 110, 112 and 114, routing layer 420 may extend across the surface of IC die 104 without departing from the scope of the embodiments herein. Routing layer 420 comprises a dielectric 404, and conductive traces 406, including conductive vias in dielectric 404. In some embodiments, dielectric 404 may comprise the same material as dielectric 302; in other embodiments, dielectric 404 may comprise a different material. Conductive traces 406 may comprise bond pads, power planes, signal traces and in some cases, passive components such as transformers, inductors, resistors, and capacitors in routing layer 420. In some embodiments, routing layer 402 may comprise several layers of dielectric 404 and conductive traces 406 with the conductive vias conductively coupling conductive traces 406 in different layers; in other embodiments, routing layer 402 may comprise a single layer of conductive traces 406 with dielectric 404 on either side and the conductive vias may conductively couple conductive traces 406 with bond pads or other conductive portions of the IC dies to which routing layer 402 is coupled, for example, IC dies 104 and 110.

Interfaces between routing layer 402 and adjacent components, for example, IC dies 104, 110, 112, 114, etc. may comprise interconnects having a pitch of less than 10 micrometers between adjacent ones of the interconnects. In some embodiments, interconnects between routing layer 402 and IC dies 110, 112, and 114 may comprise hybrid bonds, whereas interconnects between routing layer 402 and IC die 104 may comprise vias over bond pads fabricated by a damascene or semi-additive process known in the art. In other embodiments, the arrangement may be reversed, with interconnects between routing layer 402 and IC die 104 comprising hybrid bonds and interconnects between routing layer 402 and IC dies 110, 112, and 114 comprising vias in dielectric. Conductive traces 406 may be patterned to provide lateral electrical coupling between IC dies 110, 112 and 114 in some embodiments without necessitating a conductive pathway through IC die 104. Conductive traces 406 may also be patterned to provide vertical electrical coupling between IC dies 104 and IC dies 110, 112 and 114.

In many embodiments, conductive traces 406 comprise conductive lines having a spacing of less than 10 micrometers. For example, in one embodiment, conductive traces 406 comprise conductive lines having 1 micrometer line spacing; in another embodiment, conductive traces 406 may comprise conductive lines having 10 micrometer line spacing; in yet another embodiment, the smallest line spacing may be 1 micrometer, while other conductive lines may be spaced wider apart.

FIG. 5 is a simplified top view and block diagram of an example IO circuit 106 in microelectronic assembly 100, according to various embodiments. IO circuit 106 may comprise an IO PHY interface in many embodiments. The example IO circuit 106 comprises double data rate (DDR) interface; the teachings with reference to this example is applicable to any other IO circuit (e.g., Ethernet, PCIe, 3G/5G, etc.) without departing from the scope of the embodiments. IO circuit 106 may comprise one or more data registers 502, one or more command and control circuit (CAC) 504, one or more clock circuits (CLK) 506 and one or more compensator circuits (COMP) 508. Data registers 502, CAC 504, CLK 506 and COMP 508 may be located in the active region of IC die 104 and metallization stack 208. Likewise, the microcontroller circuit may be disposed in the active region and metallization stack 204 of IC die 110. Data registers 502, CAC 504, CLK 506 and COMP 508 and the microcontroller circuit in IC die 110 may be electrically coupled by conductive traces 510. Although conductive traces 510 is shown as a simplified straight line for ease of illustration, conductive traces 510 may comprise any suitable shape and structure forming a conductive pathway between the active region in IC die 110 and the active region of IC die 104, through conductive traces and vias in metallization stack 204 of IC die 110, TSVs 214 and 216 of IC die 104 and conductive traces and vias in metallization stack 208 of IC die 104. In various embodiments, one or more conductive traces 510 may couple any one of data registers 502, CAC 504, CLK 506 and COMP 508 with microcontroller circuit in IC due 110. One or more such conductive traces 510 between data registers 502 and IC die 110 may comprise (e.g., function as) data channels.

In addition, conductive traces 510 may be coupled to circuitry 512, comprising retimer circuits, and/or repeater circuits, disposed in IC die 110 and/or IC die 104. In some embodiments, the repeater circuit may comprise a linear amplifier and electronic filters. Any suitable repeater circuit known in the art may be comprised in the repeater circuit of circuitry 512. In some embodiments, the retimer circuits may comprise flip-flops and multiplexers. Any suitable retimer circuit known in the art may be comprised in the retimer circuit of circuitry 512. In some embodiments, conductive traces 510 may be coupled to a single instance of the retimer circuit and/or the repeater circuit in circuitry 512; in other embodiments, conductive traces 510 may be coupled to multiple instances of the retimer circuit and/or the repeater circuit in circuitry 512. The number and placement of circuitry 512 may be based on the length of the respective conductive trace 510 with which circuitry 512 is coupled. In many embodiments, a portion of conductive traces 510 is in IC die 104 and another portion of conductive traces 510 is in IC die 110. In some embodiments, yet another portion of conductive traces 510 may be in routing layer 402.

In some embodiments, IC die 110 may be sized to fit within a boundary of IO circuit 106 such that components of the microcontroller circuit may be as close as possible to the respective ones of data registers 502, CAC 504, CLK 506 and COMP 508 with which they are electrically coupled by conductive traces 510. Thus, for example, a circuit block that is electrically coupled with CAC 504 in IC die 110 may be located adjacent to and above CAC 504 so that the conductive pathway from that circuit block to CAC 504 is shorter than if the circuit block was not located adjacent to and over CAC 504.

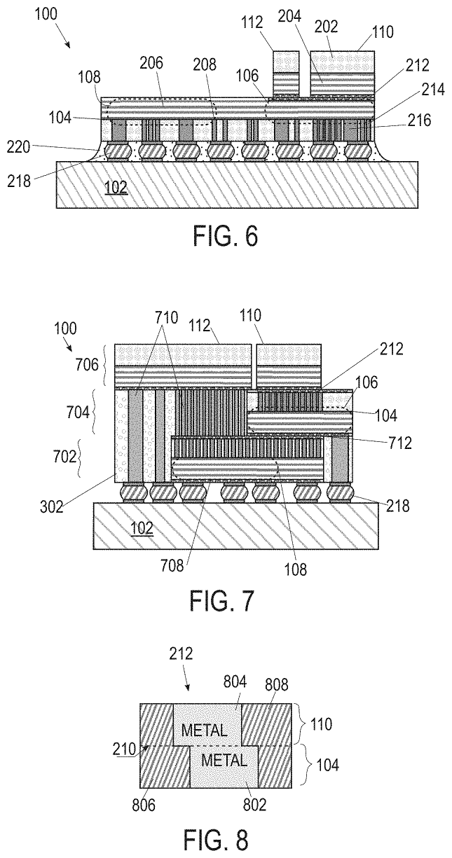

FIG. 6 is a simplified cross-sectional view of yet another example embodiment of microelectronic assembly 100 across axis BB′ of FIG. 1, according to various embodiments of the present disclosure. The embodiment shown in FIG. 3 is similar to the embodiment shown in FIG. 2, except that IC die 104 is reversed. In the embodiment shown, metallization stack 208 is proximate to metallization stack 204 of IC die 110 in a front-to-front (FTF) configuration. Note that the embodiments shown in FIGS. 2-4 show IC dies 104 and 110 in a back-to-front (BTF) configuration, with metallization stack 208 of IC die 104 distant from metallization stack 204 of IC die 110 and proximate to DTPS interconnects 218. Any of the embodiments of FIGS. 2-4 may be modified from the BTF configuration to the FTF configuration shown in FIG. 6 without departing from the scope of the embodiments. The FTF configuration may provide a shorter conductive pathway between IO circuit 106 and IC dies 110, 112 and 114.

FIG. 7 is a simplified cross-sectional view of another example embodiment of microelectronic assembly 100. Microelectronic assembly 100 comprises a plurality of layers, for example, layers 702, 704 and 706. Each layer 702, 704 and 706 comprises one or more IC dies therein. For example, IC die 708 is in layer 702, IC die 104 is in layer 704 and IC dies 110 and 114 may be in layer 706. Note that microelectronic assembly 100 may comprise any number of layers without departing from the scope of the embodiments. One or more of layers 702, 704 and 706 may comprise dielectric 302 with TDVs 710 disposed in dielectric 302. In some embodiments, dielectric 302 in each layer may comprise a different material; in other embodiments, dielectric 302 in all layers may comprise the same material; in yet other embodiments, dielectric 302 in some layers may comprise the same material, which may be different from the material in other layers.

TDVs 710 may electrically couple DTPS interconnects 218 with one or more layers (e.g., 704, 706). TDVs 710 may also electrically couple components in one layer (e.g., 702) with components in another layer (e.g., 706). In some embodiments, all TDVs 710 may be of the same size; in other embodiments, TDVs 710 may be of different sizes, for example, some may carry power and may be larger than others that carry signals and are smaller. In some embodiments, some TDVs 710 may be spaced farther apart from each other than other TDVs 710, whereas in other embodiments, TDVs 710 may all be uniformly spaced apart, depending on their functionalities, assembly footprint, and other design and manufacturing considerations.

In many embodiments, adjacent layers may be mechanically and electrically coupled by DTD interconnects having a pitch of less than 10 micrometers; for example, layers 702 and 704 may be coupled by DTD interconnects 712; layers 702 and 704 may be coupled by DTD interconnects 212. In some embodiments, DTD interconnects 712 and 212 may be distributed across the entirety of the bonding interfaces between the respective adjacent layers; in other embodiments, DTD interconnects 712 and 212 may be limited to coupled IC dies.

In the example embodiment, circuitry apart from IO circuit 106 is separated out into separate IC die 708. For example, IP core 108 may be provisioned in IC die 708 rather than IC die 104. IP core 108 may be conductively coupled to IO circuit 106 in IC die 104 in layer 704 by DTD interconnects 712. IC die 110 may be conductively coupled to IC die 104 in layer 706, forming a multi-layered package. Because the pitch of DTD interconnects 712 is of the same order of magnitude as the line spacing and pitch of conductive traces in the metallization stacks of the IC dies, there may be no effective change in functional performance (e.g., IR drop, delay, etc.) by moving IP core 108 into separate IC die 708. Further, IC die 708 may be fabricated using semiconductor processes tailored to improve performance of IP core 108, whereas IC die 104 may be fabricated using another semiconductor process tailored to improve performance of the circuits comprised therein. As a result, in some embodiments, transistors in IC die 708 may be smaller than transistors in IC die 104.

FIG. 8 shows an individual one of an example embodiment of DTD interconnects 212 comprising hybrid bonds in greater detail. Note that although one of DTD interconnects 212 is shown, the same structure and description may apply to any other DTD interconnects (e.g., 712) comprising hybrid bonds in microelectronic assembly 100. At interface 210 between IC die 104 and IC die 110, conductive contact 802 belonging to IC die 104 may bond with conductive contact 804 of IC die 110; likewise, dielectric 806 (e.g., silicon oxide, silicon nitride, silicon oxynitride, etc.) in IC die 104 may bond with dielectric 808 in IC die 110. The bonded interconnects form DTD interconnects 212, comprising hybrid bonds, providing electrical and mechanical coupling between IC die 104 and IC die 110.

In various embodiments, any of the features discussed with reference to any of FIGS. 1-8 herein may be combined with any other features to form a package with one or more IC dies as described herein, for example, to form a modified microelectronic assembly 100. Some such combinations are described above, but, in various embodiments, further combinations and modifications are possible.

Example Devices and Components

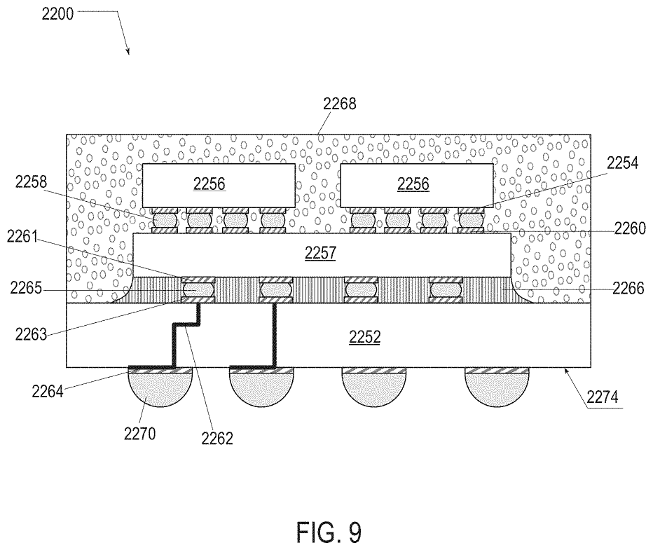

The packages disclosed herein, e.g., any of the embodiments shown in FIGS. 1-8 or any further embodiments described herein, may be included in any suitable electronic component. FIGS. 9-11 illustrate various examples of packages, assemblies, and devices that may be used with or include any of the IC packages as disclosed herein.

FIG. 9 is a side, cross-sectional view of an example IC package 2200 that may include IC packages in accordance with any of the embodiments disclosed herein. In some embodiments, the IC package 2200 may be a system-in-package (SiP).

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 10.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., high-bandwidth memory), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 10 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 9.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 9. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as RF devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

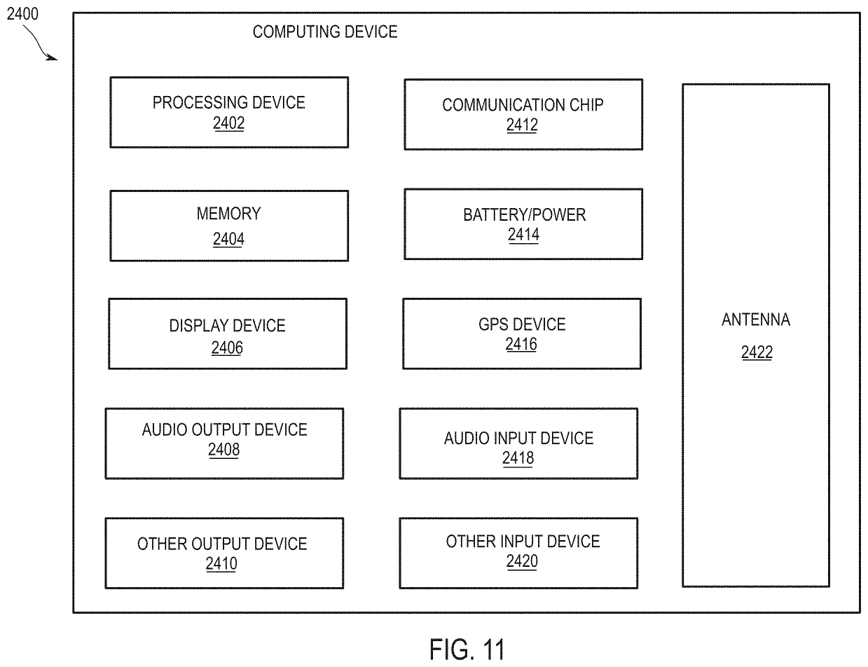

FIG. 11 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 9). In yet another example, any one or more of the components of computing device 2400 may include an IC device assembly 2300 (e.g., as shown in FIG. 10).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

The following paragraphs provide various examples of the embodiments disclosed herein.

Example 1 provides a microelectronic assembly (e.g., 100), comprising (e.g., FIG. 1): a first IC die (e.g., 104), the first IC die comprising an IO circuit (e.g., 106); and a plurality of IC dies (e.g., 110, 112, 114), the plurality of IC dies comprising a second IC die (e.g., 110), the second IC die comprising a microcontroller circuit to control the IO circuit, in which the first IC die and the plurality of IC dies are coupled with interconnects (e.g., 212, FIG. 7) having a pitch of less than 10 micrometers between adjacent ones of the interconnects.

Example 2 provides the microelectronic assembly of claim 1, in which the microelectronic assembly further comprises a third IC (e.g., 112) die in the plurality of IC dies, the third IC die comprising passive components integrated into a metallization stack of the third IC die.

Example 3 provides the microelectronic assembly of claim 2, in which the passive components comprise at least one of: inductors, resistors, and capacitors.

Example 4 provides the microelectronic assembly of any one of examples 2-3, further comprising a fourth IC die (e.g., 114) in the plurality of IC dies, the fourth IC die comprising one or more circuits to interact with the IO circuit.

Example 5 provides the microelectronic assembly of claim 4, in which the one or more circuits comprise an electrostatic discharge (ESD) protection circuit (e.g., an ESD diode).

Example 6 provides the microelectronic assembly of any one of examples 1-5, in which the IO circuit is proximate to a periphery of the first IC die.

Example 7 provides the microelectronic assembly of claim 6, in which the second IC die is adjacent to the IO circuit of the first IC die.

Example 8 provides the microelectronic assembly of claim 7, in which the IO circuit is within a boundary of a footprint of the second IC die.

Example 9 provides the microelectronic assembly of any one of examples 1-8, further comprising conductive traces (e.g., 510) between the IO circuit and the plurality of IC dies.

Example 10 provides the microelectronic assembly of claim 9, in which a portion of the conductive traces is in the first IC die and another portion of the conductive traces is in the second IC die.

Example 11 provides the microelectronic assembly of claim 9, further comprising a routing layer (e.g., 402) between the first IC die and the second IC die, the routing layer comprising the conductive traces.

Example 12 provides the microelectronic assembly of any one of examples 9-11, in which the conductive traces are coupled to least one repeater circuit (e.g., 512).

Example 13 provides the microelectronic assembly of any one of examples 9-12, in which the conductive traces are coupled to at least one retimer flip-flop circuit (e.g., 512).

Example 14 provides the microelectronic assembly of any one of examples 1-13, further comprising a dielectric (e.g., 302) surrounding the at least one of: the first IC die and the second IC die.

Example 15 provides the microelectronic assembly of claim 14, in which the dielectric comprises a compound of silicon and at least one of: oxygen, carbon, and nitrogen.

Example 16 provides the microelectronic assembly of any one of examples 14-15, further comprising TDVs in the dielectric.

Example 17 provides the microelectronic assembly of any one of examples 1-16, in which the first IC die comprises TSVs (e.g., 214, 216) to electrically couple the IO circuit with the plurality of IC dies.

Example 18 provides the microelectronic assembly of any one of examples 1-17, in which (e.g., FIG. 7): the interconnects comprise first interconnects, and the microelectronic assembly further comprises layers (e.g., 702, 704, 706) having IC dies in the layers, in which adjacent layers are coupled with second interconnects having a pitch of less than 10 micrometers between adjacent ones of the second interconnects.

Example 19 provides the microelectronic assembly of any one of examples 1-18, in which: the interconnects (e.g., 212) comprise first interconnects, and the microelectronic assembly further comprises a package substrate (e.g., 102) coupled to the first IC die with second interconnects (e.g., 218) having a pitch larger than 10 micrometers between adjacent ones of the second interconnects.

Example 20 provides the microelectronic assembly of claim 19, in which (e.g., FIG. 6): the first IC die comprises a first substrate (e.g., 206) and a first metallization stack (e.g., 208) parallel and adjacent to the first substrate, the first metallization stack comprising conductive traces in ILD, the second IC die comprises a second substrate (e.g., 202) and a second metallization stack (e.g., 204) parallel and adjacent to the second substrate, the second metallization stack comprising conductive traces in ILD, the first metallization stack of the first IC die is adjacent to the second metallization stack of the second IC die, the first metallization stack is coupled to the second metallization stack with the interconnects, and the first IC die further comprises TSVs (e.g., 214, 216) in the first substrate to electrically couple the first metallization stack with the package substrate.

Example 21 provides an IC package, comprising: a first IC die comprising an IO circuit at a periphery of the first IC die; a second IC die comprising a microcontroller circuit to control the IO circuit; and a package substrate coupled to the first IC die, in which: the first IC die is between the second IC die and the package substrate, the second IC die is adjacent to the IO circuit of the first IC die, the first IC die and the second IC die are coupled with first interconnects having a first pitch of less than 10 micrometers between adjacent ones of the first interconnects, and the first IC die and the package substrate are coupled with second interconnects having a second pitch of greater than 10 micrometers between adjacent ones of the second interconnects.

Example 22 provides the IC package of claim 21, in which the second IC die has a footprint corresponding to a boundary of the IO circuit.

Example 23 provides the IC package of any one of examples 21-22, in which: the first IC die comprises a first substrate and a first metallization stack parallel and adjacent to the first substrate, the first metallization stack comprising conductive traces in ILD, the second IC die comprises a second substrate and a second metallization stack parallel and adjacent to the second substrate, the second metallization stack comprising conductive traces in ILD, the IO circuit and the microcontroller circuit are electrically coupled by conductive pathways through the conductive traces in the first metallization stack of the first IC die, the first interconnects, and the conductive traces in the second metallization stack of the second IC die.

Example 24 provides the IC package of claim 23, in which the conductive pathways further comprise TSVs in at least one of: the first IC die and the second IC die.

Example 25 provides the IC package of claim 24, in which the TSVs comprise a first TSV for data and a second TSV for power, the second TSV having a larger cross-sectional dimension than the first TSV.

Example 26 provides the IC package of any one of examples 24-25, in which a cross-sectional dimension of the TSVs is proportional to the first pitch, with a larger first pitch corresponding to a larger cross-sectional dimension than a smaller first pitch.

Example 27 provides the IC package of any one of examples 24-26, in which a third pitch of the TSVs is equal to the first pitch.

Example 28 provides the IC package of any one of examples 24-27, in which the at least one of the first IC die and the second IC die comprising the TSVs has a thickness between 10 micrometers and 50 micrometers.

Example 29 provides the IC package of any one of examples 23-28, in which the conductive pathways comprise data channels coupled between the microcontroller circuit and data registers in the IO circuit.

Example 30 provides the IC package of any one of examples 23-29, in which the conductive pathways are coupled to at least one of: a repeater circuit and a retimer flip-flop circuit.

Example 31 provides the IC package of any one of examples 21-30, further comprising a third IC laterally adjacent to the second IC die and coupled to the first IC die with interconnects having a pitch of less than 10 micrometers between adjacent ones of the interconnects, the third IC die comprising at least one of: an ESD diode, an inductor, a capacitor, a resistor, and a circuit for timing signals communicated with the IO circuit.

Example 32 provides the IC package of any one of examples 21-31, in which the IO circuit comprises analog physical (PHY) circuitry and the microcontroller circuit comprises digital circuitry.

Example 33 provides the IC package of any one of examples 21-32, in which transistors in the second IC die are smaller than transistors in the first IC die.

Example 34 provides the IC package of any one of examples 21-33, in which (e.g., FIG. 7): the first IC die is in a first layer, the second IC die is in a second layer, and the IC package further comprises a third layer of IC dies, in which: the second layer is in between the first layer and the third layer, the third layer is coupled to the second layer with third interconnects having a pitch of less than 10 micrometers between adjacent ones of the third interconnects.

Example 35 provides the IC package of any one of examples 21-34, in which the second layer comprises a dielectric surrounding the second IC die, the dielectric comprising a compound of silicon and at least one of: oxygen, carbon and nitrogen.

Example 36 provides an IC, comprising (e.g., FIGS. 5, 7): an IO PHY interface (e.g., 106) comprising a data register (e.g., 502); and a microcontroller circuit conductively coupled to the data register, in which: the IO PHY interface is in a first IC die, the microcontroller circuit is in a second IC die, and the first IC die and the second IC die are coupled by interconnects having a pitch of less than 10 micrometers.

Example 37 provides the IC of claim 36, in which the IO PHY interface further comprises (e.g., FIG. 5): a command address and control circuit (e.g., 504); a clock circuit (e.g., 506); and a compensator circuit (e.g., 508).

Example 38 provides the IC of any one of examples 36-37, in which a conductive pathway (e.g., 510) between the microcontroller circuit and the data register is coupled to a retimer flip-flop circuit (e.g., 512).

Example 39 provides the IC of any one of examples 36-38, in which a conductive pathway between the microcontroller circuit and the data register is coupled to a repeater circuit (e.g., 512).

Example 40 provides the IC of any one of examples 36-39, in which the second IC die is within a footprint of the IO PHY interface.

Example 41 provides the IC of any one of examples 36-40, in which a first portion of a conductive pathway between the microcontroller circuit and the data register is in the first IC die and a second portion of the conductive pathway is in the second IC die.

Example 42 provides the IC of claim 41, in which a third portion of the conductive pathway is in a routing layer between the first IC die and the second IC die.

Example 43 provides the IC of any one of examples 36-42, in which transistors in the IO PHY interface in the first IC die are larger than transistors in the microcontroller circuit in the second IC die.

Example 44 provides the IC of any one of examples 36-43, further comprising passive components in a third IC die and ESD diodes in a fourth IC die, the third IC die and the fourth IC die coupled to the first IC die with interconnects having a pitch of less than 10 micrometers between adjacent ones of the interconnects.

Example 45 provides the IC of claim 44, further comprising an IP core (e.g., 108) in a third IC die (e.g., 708) in a first layer (e.g., 702), in which (e.g., FIG. 7): the IP core is conductively coupled to the IO PHY interface in the first IC die, the first IC die is in a second layer (e.g., 704) between the first layer and a third layer (e.g., 706), the second IC die is in the third layer, the third IC die is coupled to the first IC die with interconnects (e.g., 712) having a pitch of less than 10 micrometers between adjacent ones of the interconnects, and at least the first layer and the second layer comprise TDVs (e.g., 710) in a dielectric (e.g., 302).

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a first integrated circuit (IC) die, the first IC die comprising an input/output (IO) circuit; and
a plurality of IC dies, the plurality of IC dies comprising a second IC die, the second IC die comprising a microcontroller circuit to control the IO circuit,
wherein the first IC die and the plurality of IC dies are coupled with interconnects having a pitch of less than 10 micrometers between adjacent ones of the interconnects.

2. The microelectronic assembly of claim 1, wherein the microelectronic assembly further comprises a third IC die in the plurality of IC dies, the third IC die comprising passive components integrated into a metallization stack of the third IC die.

3. The microelectronic assembly of claim 2, further comprising a fourth IC die in the plurality of IC dies, the fourth IC die comprising one or more circuits to interact with the IO circuit.

4. The microelectronic assembly of claim 1, wherein the IO circuit is proximate to a periphery of the first IC die.

5. The microelectronic assembly of claim 4, wherein the second IC die is adjacent to the IO circuit of the first IC die.

6. The microelectronic assembly of claim 1, further comprising conductive traces between the IO circuit and the plurality of IC dies.

7. The microelectronic assembly of claim 6, wherein a portion of the conductive traces is in the first IC die and another portion of the conductive traces is in the second IC die.

8. The microelectronic assembly of claim 6, further comprising a routing layer between the first IC die and the second IC die, the routing layer comprising the conductive traces.

9. The microelectronic assembly of claim 1, further comprising a dielectric surrounding the at least one of: the first IC die and the second IC die.

10. The microelectronic assembly of claim 1, wherein:
the interconnects comprise first interconnects, and
the microelectronic assembly further comprises layers having IC dies in the layers, wherein adjacent layers are coupled with second interconnects having a pitch of less than 10 micrometers between adjacent ones of the second interconnects.

11. An IC package, comprising:
a first IC die comprising an IO circuit at a periphery of the first IC die;
a second IC die comprising a microcontroller circuit to control the IO circuit; and
a package substrate coupled to the first IC die,
wherein:
the first IC die is between the second IC die and the package substrate,
the second IC die is adjacent to the IO circuit of the first IC die,
the first IC die and the second IC die are coupled with first interconnects having a first pitch of less than 10 micrometers between adjacent ones of the first interconnects, and
the first IC die and the package substrate are coupled with second interconnects having a second pitch of greater than 10 micrometers between adjacent ones of the second interconnects.

12. The IC package of claim 11, wherein the second IC die has a footprint corresponding to a boundary of the IO circuit.

13. The IC package of claim 11, wherein:
the first IC die comprises a first substrate and a first metallization stack parallel and adjacent to the first substrate, the first metallization stack comprising conductive traces in ILD,
the second IC die comprises a second substrate and a second metallization stack parallel and adjacent to the second substrate, the second metallization stack comprising conductive traces in interlayer dielectric (ILD),
the IO circuit and the microcontroller circuit are electrically coupled by conductive pathways through the conductive traces in the first metallization stack of the first IC die, the first interconnects, and the conductive traces in the second metallization stack of the second IC die.

14. The IC package of claim 13, wherein the conductive pathways further comprise TSVs in at least one of: the first IC die and the second IC die.

15. The IC package of claim 14, wherein the TSVs comprise a first TSV for data and a second TSV for power, the second TSV having a larger cross-sectional dimension than the first TSV.

16. The IC package of claim 11, further comprising a third IC laterally adjacent to the second IC die and coupled to the first IC die with interconnects having a pitch of less than 10 micrometers between adjacent ones of the interconnects, the third IC die comprising at least one of: an ESD diode, an inductor, a capacitor, a resistor, and a circuit for timing signals communicated with the IO circuit.

17. The IC package of claim 11, wherein:
the first IC die is in a first layer,
the second IC die is in a second layer,
the IC package further comprises a third layer of IC dies,
the second layer is in between the first layer and the third layer, and
the third layer is coupled to the second layer with third interconnects having a pitch of less than 10 micrometers between adjacent ones of the third interconnects.

18. An IC, comprising:
an IO PHY interface comprising a data register; and
a microcontroller circuit conductively coupled to the data register,
wherein:
the IO PHY interface is in a first IC die,
the microcontroller circuit is in a second IC die, and
the first IC die and the second IC die are coupled by interconnects having a pitch of less than 10 micrometers.

19. The IC of claim 18, wherein a conductive pathway between the microcontroller circuit and the data register is coupled to at least one of a retimer flip-flop circuit and a repeater circuit.

20. The IC of claim 18, further comprising passive components in a third IC die and ESD diodes in a fourth IC die, the third IC die and the fourth IC die coupled to the first IC die with interconnects having a pitch of less than 10 micrometers between adjacent ones of the interconnects.
